(19) United States
(12) Patent Application Publication
(10) Pub. No.: US 2024/0316968 A1
(43) Pub. Date: Sep. 26, 2024

(54) HOUSING STRUCTURE AND IMAGE FORMATION DEVICE

(71) Applicant: FUJIFILM CORPORATION, Minato-ku, Tokyo (JP)

(72) Inventor: Masaaki TAKENOUCHI, Kanagawa (JP)

(21) Appl. No.: 18/579,509

(22) PCT Filed: Jul. 1, 2022
(86) PCT No.: PCT/JP2022/026520

§ 371 Date: Jan. 16, 2024

(30) Foreign Application Priority Data
Aug. 2, 2021 (JP) 2021-126952

(51) Int. Cl. B41J 29/13; G03G 21/16

(52) U.S. Cl. CPC B41J 29/13; G03G 21/1633

(57) ABSTRACT

A housing structure includes a cover portion including a first cover portion provided on one surface of a first housing, and a second cover portion provided on the one surface of the first housing below the first cover portion; a first inclined portion provided at a lower end portion of the first cover portion and inclined toward an inside of the first housing; a second inclined portion provided at an upper end portion of the second cover portion and inclined toward the inside of the first housing; and a first handle portion which is a handle for opening and closing the cover portion, in which a distal end portion of the handle is located on an inclined surface of the first inclined portion, and which is formed to include a grip portion of the handle on a side opposite to the inclined surface of the first inclined portion.

### TECHNICAL FIELD

The present disclosure relates to a housing structure and an image formation device.

### BACKGROUND ART

Japanese Design Registration No. 1660831 discloses that in a printer in which a large and easy-to-grip handle for opening and closing a cover is provided at a central right portion in a front view, a line on which the handle is located is linearly aligned with upper surface lines of left and right components, thereby making it easy to access the handle and providing a sense of unity to overall design.

### SUMMARY OF INVENTION

### Technical Problem

In a housing structure, an inclined portion may be partially provided. In a case where a handle for opening and closing a cover that covers a housing is attached to the inclined portion, the inclined portion is not continuous, whereby aesthetic appeal deteriorates.

Therefore, an object of the disclosure is to provide a housing structure in which aesthetic appeal is improved by maintaining the continuity of an inclined portion provided in a housing while providing a handle in the inclined portion.

### Solution to Problem

According to a first aspect, a housing structure includes a cover portion including a first cover portion provided on one surface of a first housing, and a second cover portion provided on the one surface of the first housing below the first cover portion; a first inclined portion provided at a lower end portion of the first cover portion and inclined toward an inner side of the first housing; a second inclined portion provided at an upper end portion of the second cover portion and inclined toward the inner side of the first housing; and a first handle portion, which is a handle for opening and closing the cover portion, in which a distal end portion of the handle is located on an inclined surface of the first inclined portion, and which is formed to include a grip portion of the handle on an opposite side from the inclined surface of the first inclined portion.

In a second aspect, a covering portion provided below the distal end portion of the first handle portion and covering an upper end surface of the second cover portion is provided.

In a third aspect, the covering portion is inclined in the same direction as the second inclined portion.

In a fourth aspect, the first inclined portion is formed over the lower end portion of the first cover portion.

In a fifth aspect, the second inclined portion is formed over the upper end portion of the second cover portion.

In a sixth aspect, the housing structure includes a second housing connected to the first housing, and the second housing includes a second housing inclined portion provided at an upper end portion of a surface on the same side as the one surface and formed to be continuous with the second inclined portion.

In a seventh aspect, the second housing includes a second housing cover portion provided on the surface on the same side as the one surface of the first housing and provided with the second housing inclined portion, and a second handle portion for opening and closing the second housing cover portion. The second handle portion is formed to include a second housing recess provided on an upper surface of the second housing and open toward the second housing inclined portion.

In an eighth aspect, the housing structure includes a third housing connected to the second housing, and the third housing includes a third inclined portion provided at an upper end portion of a surface on the same side as the one surface and formed over the second housing inclined portion.

In a ninth aspect, the third housing includes a third cover portion provided on the surface on the same side as the one surface of the first housing and provided with the third inclined portion, and a third handle portion for opening and closing the third cover portion. The third handle portion is formed to include a third recess provided on an upper surface of the third housing and open toward the third inclined portion.

In a tenth aspect, the third inclined portion is provided with a first notification unit.

In an eleventh aspect, the housing structure includes a fourth housing connected to the third housing, and the fourth housing includes a fourth inclined portion provided at an upper end portion of a surface on the same side as the one surface and formed to be continuous with the third inclined portion.

In a twelfth aspect, the fourth housing includes a fourth cover portion provided on the surface on the same side as the one surface of the first housing and provided with the fourth inclined portion, and a fourth handle portion for opening and closing the fourth cover portion. The fourth handle portion is formed to include a fourth recess provided on an upper surface of the fourth housing and open toward the fourth inclined portion.

In a thirteenth aspect, the fourth inclined portion is provided with a second notification unit.

In a fourteenth aspect, the housing structure includes a fifth housing connected to an opposite side from a side on which the second housing is connected to the first housing, and the fifth housing includes a fifth inclined portion provided at an upper end portion of a surface on the same side as the one surface and formed to be continuous with the second inclined portion.

In a fifteenth aspect, the fifth housing includes a fifth cover portion provided on the surface on the same side as the one surface of the first housing and provided with the fifth inclined portion, and a fifth handle portion for opening and closing the fifth cover portion. The fifth handle portion is formed to include a fifth recess provided on an upper surface of the fifth housing and open toward the fifth inclined portion.

In a sixteenth aspect, the fifth inclined portion is provided with a third notification unit.

In a seventeenth aspect, the housing structure includes a sixth housing connected to the fifth housing, and the sixth housing includes a sixth inclined portion provided at an upper end portion of a surface on the same side as the one surface and formed to be continuous with the fifth inclined portion.

In an eighteenth aspect, the sixth housing includes a sixth cover portion provided on the surface on the same side as the one surface of the first housing and provided with the sixth inclined portion, and a sixth handle portion for opening and closing the sixth cover portion. The sixth handle portion is formed to include a sixth recess provided on an upper surface of the sixth housing and open toward the sixth inclined portion.

In a nineteenth aspect, the sixth inclined portion is provided with a fourth notification unit.

According to a twentieth aspect, an image formation device includes the housing structure according to any one of the first to nineteenth aspects.

### Advantageous Effects of Invention

According to the configuration of the first aspect, the aesthetic appeal is improved compared to a case in which a separate handle portion protruding to the outside of the housing is attached to the inclined portion.

According to the configuration of the second aspect, the aesthetic appeal is improved compared to a configuration in which the upper end surface of the second cover portion is exposed.

According to the configuration of the third aspect, compared to a case in which the covering portion is inclined in a direction different from that of the second inclined portion, it becomes difficult to view the upper end surface of the second cover portion in a narrow space, and the aesthetic appeal is improved.

According to the configuration of the fourth aspect, the aesthetic appeal is improved compared to a case in which the inclined portion is provided only at a part of the lower end portion of the first cover portion.

According to the configuration of the fifth aspect, the aesthetic appeal is improved compared to a case in which the inclined portion is provided only at a part of the upper end portion of the second cover portion.

According to the configuration of the sixth aspect, the aesthetic appeal is improved compared to a configuration in which the inclined portions are offset between the first housing and the second housing.

According to the configuration of the seventh aspect, the aesthetic appeal is improved compared to a case in which the second handle is provided as a separate body protruding to the outside.

According to the configuration of the eighth aspect, the aesthetic appeal is improved compared to a case in which the inclined portions are offset between the second housing and the third housing.

According to the configuration of the ninth aspect, in the third housing, the aesthetic appeal is improved compared to a case in which a separate handle is provided on the inclined portion.

According to the configuration of the tenth aspect, the notification unit is easily recognized compared to a case in which the notification unit is provided at a portion other than the inclined portion.

According to the configuration of the eleventh aspect, the aesthetic appeal is improved compared to a case in which the inclined portions are offset between the third housing and the fourth housing.

According to the configuration of the twelfth aspect, in the fourth housing, the aesthetic appeal is improved compared to a case in which a separate handle is provided on the inclined portion.

According to the configuration of the thirteenth aspect, the notification unit is easily recognized compared to a case in which the notification unit is provided at a portion other than the inclined portion.

According to the configuration of the fourteenth aspect, the aesthetic appeal is improved compared to a case in which the inclined portions are offset between the first housing and the fifth housing.

According to the configuration of the fifteenth aspect, in the fifth housing, the aesthetic appeal is improved compared to a case in which a separate handle is provided on the inclined portion.

According to the configuration of the sixteenth aspect, the notification unit is easily recognized compared to a case in which the notification unit is provided at a portion other than the inclined portion.

According to the configuration of the seventeenth aspect, the aesthetic appeal is improved compared to a case in which the inclined portions are offset between the fifth housing and the sixth housing.

According to the configuration of the eighteenth aspect, in the sixth housing, the aesthetic appeal is improved compared to a case in which a separate handle is provided on the inclined portion.

According to the configuration of the nineteenth aspect, the notification unit is easily recognized compared to a case in which the notification unit is provided at a portion other than the inclined portion.

According to the configuration of the twentieth aspect, the aesthetic appeal of the image formation device is improved compared to a case in which the housing structure according to the first to nineteenth aspects is not provided.

### BRIEF DESCRIPTION OF DRAWINGS

FIG. 1 is a perspective view showing one form example of a housing structure according to the present embodiment.

FIG. 2 is a partial enlarged view showing one form example of a handle according to the present embodiment.

FIG. 3 is a partial cross-section showing one form example of the handle according to the present embodiment.

FIG. 4 is a perspective view showing one form example of the housing structure according to the present embodiment.

FIG. 5 is a partial enlarged view showing one form example of a handle according to the present embodiment.

FIG. 6 is a partial cross-sectional view showing one form example of the handle according to the present embodiment.

FIG. 7 is a perspective view showing one form example of the housing structure according to the present embodiment.

FIG. 8 is a partial perspective view showing one form example of the housing structure according to the present embodiment.

FIG. 9 is a partial perspective view showing one form example of the housing structure according to the present embodiment.

FIG. 10 is a partial perspective view showing one form example of the housing structure according to the present embodiment.

FIG. 11 is a partial perspective view showing one form example of the housing structure according to the present embodiment.

FIG. 12 is a perspective view showing one modification example of the housing structure according to the present embodiment.

### DESCRIPTION OF EMBODIMENTS

Hereinafter, one example of an embodiment according to the disclosure will be described with reference to the drawings.

### (Housing Structure)

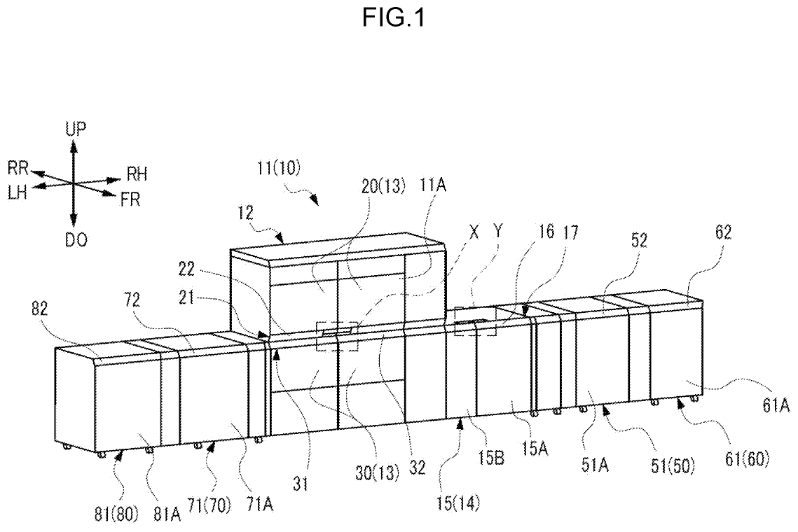

An image formation device 10 and a housing structure 11 according to the present embodiment will be described. FIG. 1 is a perspective view showing the housing structure 11.

An arrow UP shown in the drawings indicates an upward direction (namely, a vertically upward direction), and an arrow DO indicates a downward direction (namely, a vertically downward direction). In addition, an arrow LH shown in the drawings indicates a left direction, and an arrow RH indicates a right direction. In addition, an arrow FR shown in the drawings indicates a front direction, and an arrow RR indicates a rear direction. Since these directions are directions determined for convenience of description, a device configuration is not limited to these directions. In addition, in a case in which each position is indicated with respect to a certain reference, each position may be indicated with the reference omitted. Namely, for example, an “upper portion of a device” may be simply referred to as an “upper portion”.

In addition, in the following description, an “up-down direction” may be used to mean “both the upward direction and the downward direction” or “one of the upward direction and the downward direction”. A “left-right direction” may be used to mean “both the right direction and the left direction” or “one of the right direction and the left direction”. The “left-right direction” can also be referred to as a lateral direction or a horizontal direction. A “front-rear direction” may be used to mean “both the front direction and the rear direction” or “one of the front direction and the rear direction”. The “front-rear direction” can also be referred to as a lateral direction or a horizontal direction. In addition, the up-down direction, the left-right direction, and the front-rear direction are directions intersecting each other (specifically, directions orthogonal to each other).

The image formation device 10 shown in FIG. 1 is a device that forms an image. The image formation device 10 forms an image on a sheet as a recording medium using an inkjet method or an electrophotographic method as one example. The image formation device 10 includes the housing structure 11. Although not shown, various devices for enabling the image formation device 10 to function are housed inside the housing structure 11. As shown in FIG. 1, the housing structure 11 includes a housing 12 and a cover portion 13.

The housing structure 11 is one example of a “housing structure”. Hereinafter, each part of the housing structure 11 will be described.

### (Housing)

As shown in FIG. 1, the housing 12 is a housing that forms a main portion of the housing structure 11. The housing 12 is one example of a “first housing”. The housing 12 has a substantially rectangular parallelepiped shape as one example. The housing 12 is formed by sheet metal working as one example.

As shown in FIG. 1, the housing 12 includes the cover portion 13 on a front surface 11A. The cover portion 13 is openable and closable, and an internal structure of the housing 12 is exposed to the outside by opening the cover portion 13. The cover portion 13 is one example of a “cover portion”, and the front surface 11A of the housing 12 is one example of “one surface of the first housing”.

### (Cover Portion)

As shown in FIG. 1, the cover portion 13 includes upper cover portions 20 and lower cover portions 30. The upper cover portions 20 form an upper portion of the cover portion 13. The lower cover portions 30 form a lower portion of the cover portion 13. The upper cover portion 20 is one example of an “upper cover portion”, and the lower cover portion 30 is one example of a “lower cover portion”.

As one example, the upper cover portions 20 and the lower cover portions 30 may have different colors. In the present specification, “being different in color” includes not only a case in which chromaticity, saturation, or brightness is different, but also a case in which gloss is different. As one example, in the housing structure 11, the upper cover portions 20 may be painted in black, and the lower cover portions 30 may be painted in white. In addition, an upper portion of the housing 12 may also be painted in black, and a lower portion of the housing 12 may be painted in white.

### (Upper Cover Portion)

An upper inclined portion 22 is provided at a lower end portion 21 of the upper cover portion 20. The upper inclined portion 22 is one example of a “first inclined portion”.

The upper inclined portion 22 is inclined toward the inside of the housing 12 at the lower end portion 21 of the upper cover portion 20. In other words, the upper inclined portion 22 is inclined in a direction in which a thickness of the housing 12 in the front-rear direction decreases as the housing 12 extends downward. In addition, as shown in FIG. 1, the upper inclined portion 22 is formed over the lower end portion 21 of the upper cover portion 20. Specifically, the upper inclined portion 22 is formed from a left end to a right end of the lower end portion 21 of the upper cover portion 20. Here, in the description of an inclined portion in the present specification, “being formed over” indicates not only a form in which an inclined surface is continuous without a gap or a step, but also a form in which the presence of a step or a gap due to design dimensional errors or specifications is allowed.

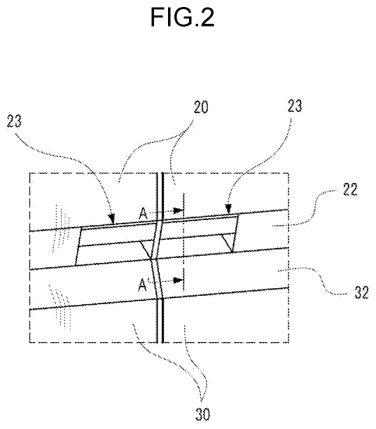

FIG. 2 is a partial enlarged view showing a region X in FIG. 1 in an enlarged manner. As shown in FIGS. 1 and 2, housing handles 23 are provided at the lower end portions 21 of the upper cover portions 20. As one example, one housing handle 23 is provided on each of a pair of the upper cover portions 20. The housing handles 23 are provided to open and close the cover portion 13. As shown in FIG. 2, the housing handle 23 forms apart of an inclined surface of the upper inclined portion 22 along the inclined surface.

### (Lower Cover Portion)

A lower inclined portion 32 is provided at an upper end portion 31 of the lower cover portion 30. The lower inclined portion 32 is one example of a “second inclined portion”.

The lower inclined portion 32 is inclined toward the inside of the housing 12 at the upper end portion 31 of the lower cover portion 30. In other words, the lower inclined portion 32 is inclined in a direction in which the thickness of the housing 12 in the front-rear direction decreases as the housing 12 extends upward. In addition, as shown in FIG. 1, the lower inclined portion 32 is formed over the upper end portion 31 of the lower cover portion 30. Specifically, the lower inclined portion 32 is formed from a left end to a right end of the upper end portion 31 of the lower cover portion 30.

### (Housing Handle)

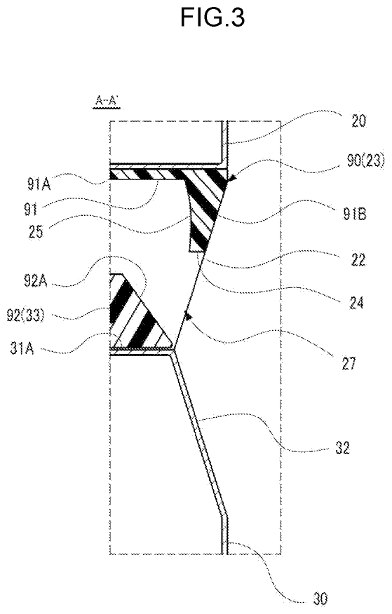

FIG. 3 is a view showing a cross-section taken along line A-A′ in FIG. 2. As shown in FIGS. 2 and 3, the housing handle 23 has a handle shape including a distal end portion 24 and a grip portion 25. As shown in FIG. 3, the distal end portion 24 is provided to be located on the inclined surface of the upper inclined portion 22. In addition, the grip portion 25 is provided on a side opposite to the inclined surface of the upper inclined portion 22. Specifically, the housing handle 23 is formed by attaching a resin member 90 to the lower end portion 21 of the upper cover portion 20. The resin member 90 may be subjected to black painting having a metallic feel.

The resin member 90 includes an upper portion 91 and a lower portion 92. As shown in FIG. 3, the upper portion 91 is a member having a substantially L-shape in a cross-sectional view taken along line A-A′. The upper portion 91 includes a main body portion 91A attached to the upper cover portion 20, and a protruding portion 91B protruding downward from an end portion on an upper inclined portion 22 side of the main body portion 91A. A distal end of the protruding portion 91B is formed as the distal end portion 24. A side of the protruding portion 91B opposite to the upper inclined portion 22 is formed as the grip portion 25. An opening 27 is formed between the distal end portion 24 and the lower cover portion 30 by providing the housing handle 23.

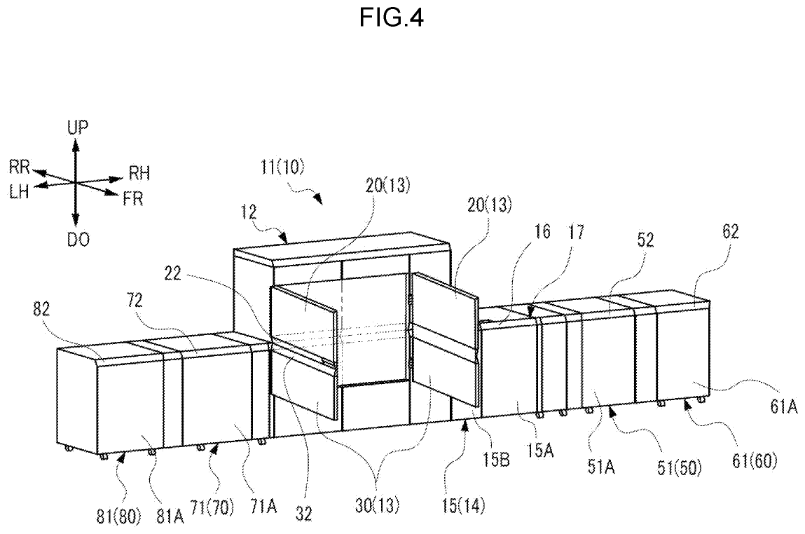

FIG. 4 is a perspective view showing a state where the cover portion 13 of the housing structure 11 is opened. When an operator operates the housing handles 23 to open the cover portion 13, the operator inserts the fingers from the openings 27, and hooks the fingers on the grip portions 25. Namely, the grip portions 25 function as finger hook portions on which the operator hooks the fingers. In this state, the operator opens the cover portion 13 as shown in FIG. 4 by pulling the housing handles 23 toward the front side of the housing structure 11. As a result, an internal structure of the housing structure 11 is exposed. As one example, as shown in FIG. 4, the cover portion 13 is a double-swing door that is openable and closable by vertical hinges.

### (Covering Portion)

A covering portion 33 is provided on an upper end surface 31A of the lower cover portion 30 below the housing handle 23. Specifically, the covering portion 33 is formed by attaching the lower portion 92 to the upper end surface 31A of the lower cover portion 30. As shown in FIG. 3, the lower portion 92 is a member having a substantially triangular shape in a cross-sectional view taken along line A-A′. An inclined surface 92A of the lower portion 92 is inclined in the same direction as the lower inclined portion 32. Namely, the inclined surface 92A is inclined such that a thickness of the lower portion 92 decreases as the lower portion 92 extends upward. The lower portion 92 is subjected to black painting having a metallic feel. Accordingly, the housing handle 23 and the covering portion 33 have similar appearances, so that the visibility of the covering portion 33 when viewed diagonally from above is reduced.

### (Post-Processing Module Housing)

As shown in FIG. 1, the image formation device 10 may further include a post-processing module 14. The post-processing module 14 is connected to the housing 12, and performs post-processing on sheets. The post-processing module 14 includes a post-processing module housing 15. The post-processing module housing 15 is one example of a “second housing”. As one example, as shown in FIG. 1, the post-processing module housing 15 is connected to a lower side surface of the housing 12 in the right direction.

The post-processing module housing 15 includes a post-processing module inclined portion 16 at an upper end portion 17 of a front surface of the housing. The post-processing module inclined portion 16 is one example of a “second housing inclined portion”. The post-processing module inclined portion 16 is formed to be continuous with the lower inclined portion 32 of the housing 12.

Namely, the post-processing module inclined portion 16 is provided on an extension line of the lower inclined portion 32. Here, in the description of an inclined portion in the present specification, “being formed to be continuous” indicates not only a form in which two inclined surfaces are linearly continuous without a gap or a step, but also a form in which the presence of a step or a gap due to design dimensional errors or specifications is allowed.

The post-processing module housing 15 includes a post-processing module right cover portion 15A and a post-processing module left cover portion 15B. The post-processing module right cover portion 15A and the post-processing module left cover portion 15B are openable and closable, and an internal structure of the post-processing module housing 15 is exposed to the outside by opening the post-processing module right cover portion 15A and the post-processing module left cover portion 15B. As one example, the post-processing module right cover portion 15A and the post-processing module left cover portion 15B are double-swing doors that are openable and closable by vertical hinges. The post-processing module right cover portion 15A or the post-processing module left cover portion 15B is one example of a “second housing cover portion”. Hereinafter, the post-processing module right cover portion 15A will be described, and the post-processing module left cover portion 15B also has the same configuration.

The post-processing module right cover portion 15A is provided on the front surface of the post-processing module housing 15. The post-processing module right cover portion 15A is provided with the post-processing module inclined portion 16.

### (Post-Processing Module Housing Handle)

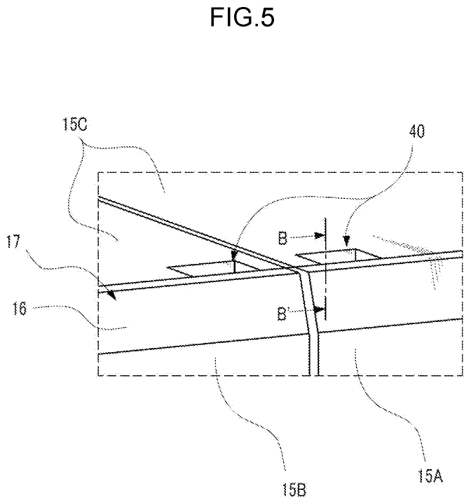

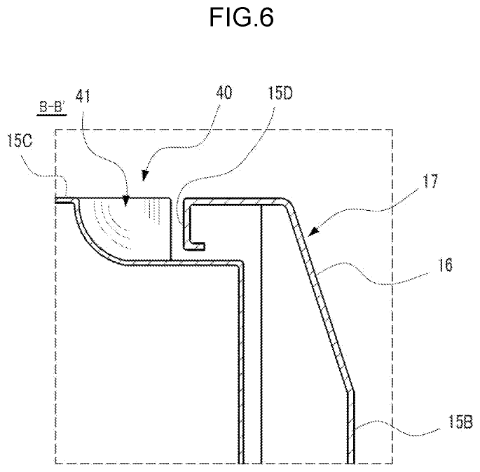

FIG. 5 is a partial enlarged view showing a region Y in FIG. 1 in an enlarged manner. FIG. 6 is a view showing a cross-section taken along line B-B′ in FIG. 5. As shown in FIGS. 5 and 6, the post-processing module housing 15 includes a post-processing module housing handle 40 for opening and closing the post-processing module right cover portion 15A on an upper surface 15C. The post-processing module housing handle 40 is formed to include a post-processing module housing recess 41 provided on the upper surface 15C. The post-processing module housing recess 41 is open upward and is open toward the post-processing module inclined portion 16. The post-processing module housing handle 40 is one example of a “second housing handle portion”, and the post-processing module housing recess 41 is one example of a “second housing recess”.

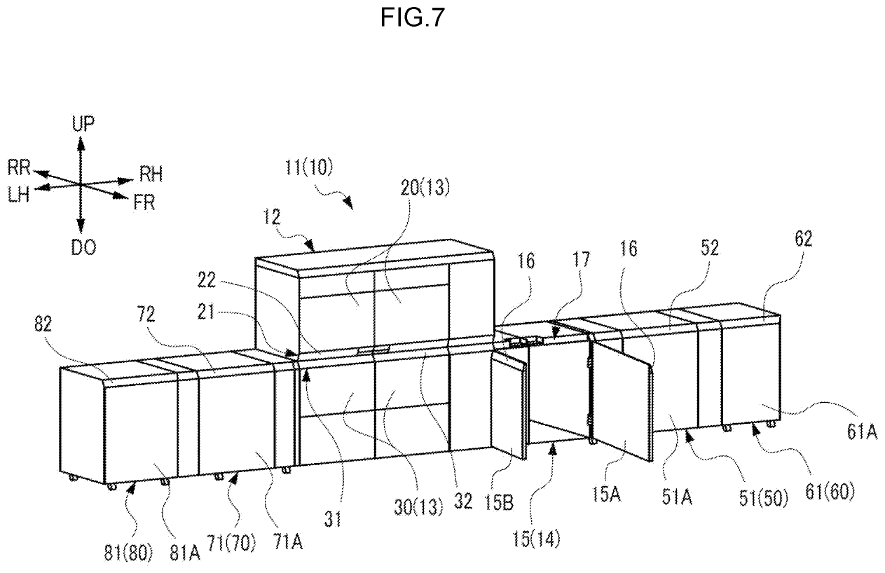

FIG. 7 is a perspective view showing a state where the post-processing module right cover portion 15A and the post-processing module left cover portion 15B are opened. When an operator operates the post-processing module housing handle 40 to open the post-processing module right cover portion 15A, the operator inserts the fingers from above the post-processing module housing recess 41, and hooks the fingers on a grip portion 15D of the post-processing module right cover portion 15A. In this state, the operator opens the post-processing module right cover portion 15A as shown in FIG. 7 by pulling the post-processing module housing handle 40 toward the front side of the post-processing module housing 15. As a result, an internal structure of the post-processing module housing 15 is exposed.

### (First Sheet Ejection Module Housing)

As shown in FIG. 1, the image formation device 10 may further include a first sheet ejection module 50. The first sheet ejection module 50 is connected to the image formation device 10, and ejects a sheet having a predetermined size. The first sheet ejection module 50 includes a first sheet ejection module housing 51. The first sheet ejection module housing 51 is one example of a “third housing”. As one example, as shown in FIG. 1, the first sheet ejection module housing 51 is connected to a side surface of the post-processing module housing 15 in the right direction.

The first sheet ejection module housing 51 includes a first sheet ejection module inclined portion 52 at an upper end portion 55 of a front surface of the housing. The first sheet ejection module inclined portion 52 is one example of a “third inclined portion”. The first sheet ejection module inclined portion 52 is formed to be continuous with the post-processing module inclined portion 16. Namely, the first sheet ejection module inclined portion 52 is provided on an extension line of the post-processing module inclined portion 16.

The first sheet ejection module housing 51 includes a first sheet ejection module cover 51A. The first sheet ejection module cover 51A is openable and closable, and an internal structure of the first sheet ejection module housing 51 is exposed to the outside by opening the first sheet ejection module cover 51A. As one example, the first sheet ejection module cover 51A is a single-swing door that is openable and closable by a vertical hinge. The first sheet ejection module cover 51A is one example of a “third cover portion”.

The first sheet ejection module cover 51A is provided on the front surface of the first sheet ejection module housing 51. The first sheet ejection module cover 51A is provided with the first sheet ejection module inclined portion 52. In addition, a through-hole is provided in the first sheet ejection module inclined portion 52 of the first sheet ejection module cover 51A at a position corresponding to a first sheet ejection module notification unit 54 to be described later. Accordingly, the first sheet ejection module notification unit 54 becomes visible to an operator.

### (First Sheet Ejection Module Housing Handle)

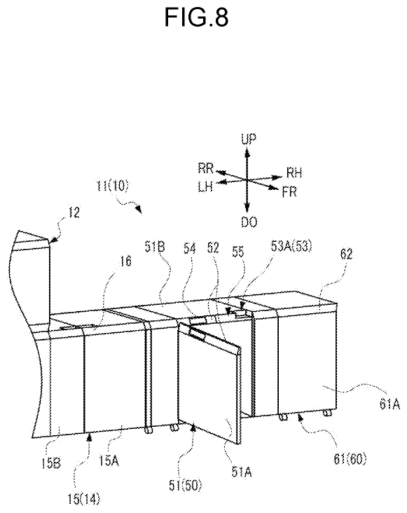

FIG. 8 is a perspective view showing the first sheet ejection module housing 51 in an enlarged manner. As shown in FIG. 8, the first sheet ejection module housing 51 includes a first sheet ejection module housing handle 53 for opening and closing the first sheet ejection module cover 51A. The first sheet ejection module housing handle 53 is formed to include a first sheet ejection module housing recess 53A provided on an upper surface 51B. The first sheet ejection module housing recess 53A is open upward and is open toward the first sheet ejection module inclined portion 52. The first sheet ejection module housing handle 53 is one example of a “fourth handle portion”, and the first sheet ejection module housing recess 53A is one example of a “fourth recess”.

When an operator operates the first sheet ejection module housing handle 53 to open the first sheet ejection module cover 51A, the operator inserts the fingers from above the first sheet ejection module housing recess 53A, and hooks the fingers on a grip portion of the first sheet ejection module cover 51A. In this state, the operator opens the first sheet ejection module cover 51A as shown in FIG. 8 by pulling the first sheet ejection module housing handle 53 toward the front side of the first sheet ejection module housing 51. As a result, an internal structure of the first sheet ejection module housing 51 is exposed.

### (First Sheet Ejection Module Notification Unit)

As shown in FIG. 8, the first sheet ejection module housing 51 includes the first sheet ejection module notification unit 54 on the first sheet ejection module inclined portion 52. The first sheet ejection module notification unit 54 is one example of a “first notification unit”. The first sheet ejection module notification unit 54 makes a notification regarding an operation state of the first sheet ejection module 50. As one example, the first sheet ejection module notification unit 54 notifies that a sheet jam has occurred in a conveyance path inside the first sheet ejection module 50. Examples of the first sheet ejection module notification unit 54 include a lighting device such as a light emitting diode (LED) lamp and a screen display device such as a liquid crystal display or an electronic luminescent (EL) display.

The first sheet ejection module notification unit 54 is disposed to fit within an inclined surface of the first sheet ejection module inclined portion 52. Namely, an upper end edge of the first sheet ejection module notification unit 54 is lower than an upper end of the first sheet ejection module inclined portion 52. In addition, a lower end edge of the first sheet ejection module notification unit 54 is higher than a lower end of the first sheet ejection module inclined portion 52.

### (Second Sheet Ejection Module Housing)

As shown in FIG. 1, the image formation device 10 may further include a second sheet ejection module 60. The second sheet ejection module 60 is connected to the image formation device 10, and ejects a sheet having a predetermined size. The second sheet ejection module 60 includes a second sheet ejection module housing 61. The second sheet ejection module housing 61 is one example of a “fourth housing”. As one example, as shown in FIG. 1, the second sheet ejection module housing 61 is connected to a side surface of the first sheet ejection module 50 in the right direction.

The second sheet ejection module housing 61 includes a second sheet ejection module inclined portion 62 at an upper end portion 65 of a front surface of the housing. The second sheet ejection module inclined portion 62 is one example of a “fourth inclined portion”. The second sheet ejection module inclined portion 62 is formed to be continuous with the first sheet ejection module inclined portion 52. Namely, the second sheet ejection module inclined portion 62 is provided on an extension line of the first sheet ejection module inclined portion 52.

The second sheet ejection module housing 61 includes a second sheet ejection module cover 61A. The second sheet ejection module cover 61A is openable and closable, and an internal structure of the second sheet ejection module housing 61 is exposed to the outside by opening the second sheet ejection module cover 61A. As one example, the second sheet ejection module cover 61A is a single-swing door that is openable and closable by a vertical hinge. The second sheet ejection module cover 61A is one example of a “fourth cover portion”.

The second sheet ejection module cover 61A is provided on the front surface of the second sheet ejection module housing 61. The second sheet ejection module cover 61A is provided with the second sheet ejection module inclined portion 62. In addition, a through-hole is provided in the second sheet ejection module inclined portion 62 of the second sheet ejection module cover 61A at a position corresponding to a second sheet ejection module notification unit 64 to be described later. Accordingly, the second sheet ejection module notification unit 64 becomes visible to an operator.

### (Second Sheet Ejection Module Housing Handle)

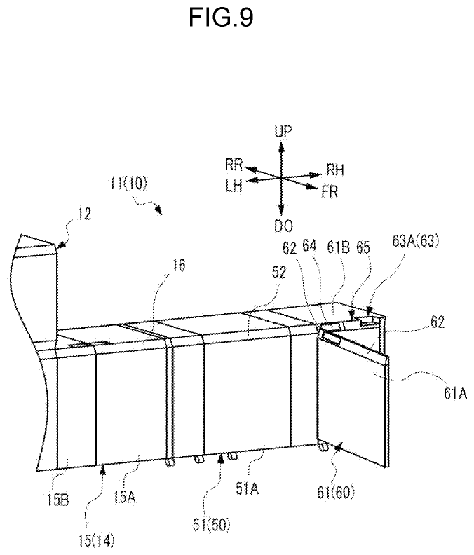

FIG. 9 is a perspective view showing the second sheet ejection module housing 61 in an enlarged manner. As shown in FIG. 9, the second sheet ejection module housing 61 includes a second sheet ejection module housing handle 63 for opening and closing the second sheet ejection module cover 61A. The second sheet ejection module housing handle 63 is formed to include a second sheet ejection module housing recess 63A provided on an upper surface 61B. The second sheet ejection module housing recess 63A is open upward and is open toward the second sheet ejection module inclined portion 62. The second sheet ejection module housing handle 63 is one example of the “fourth handle portion”, and the second sheet ejection module housing recess 63A is one example of the “fourth recess”.

When an operator operates the second sheet ejection module housing handle 63 to open the second sheet ejection module cover 61A, the operator inserts the fingers from above the second sheet ejection module housing recess 63A, and hooks the fingers on a grip portion of the second sheet ejection module cover 61A. In this state, the operator opens the second sheet ejection module cover 61A as shown in FIG. 9 by pulling the second sheet ejection module housing handle 63 toward the front side of the second sheet ejection module housing 61. As a result, an internal structure of the second sheet ejection module housing 61 is exposed.

### (Second Sheet Ejection Module Notification Unit)

As shown in FIG. 9, the second sheet ejection module housing 61 includes the second sheet ejection module notification unit 64 on the second sheet ejection module inclined portion 62. The second sheet ejection module notification unit 64 is one example of a “second notification unit”. The second sheet ejection module notification unit 64 makes a notification regarding an operation state of the second sheet ejection module 60. As one example, the second sheet ejection module notification unit 64 notifies that a sheet jam has occurred in a conveyance path inside the second sheet ejection module 60. Examples of the second sheet ejection module notification unit 64 include a lighting device such as a light emitting diode (LED) lamp and a screen display device such as a liquid crystal display or an electronic luminescent (EL) display.

The second sheet ejection module notification unit 64 is disposed to fit within an inclined surface of the second sheet ejection module inclined portion 62. Namely, an upper end edge of the second sheet ejection module notification unit 64 is lower than an upper end of the second sheet ejection module inclined portion 62.

In addition, a lower end edge of the second sheet ejection module notification unit 64 is higher than a lower end of the second sheet ejection module inclined portion 62.

### (First Sheet Feeding Module Housing)

As shown in FIG. 1, the image formation device 10 may further include a first sheet feeding module 70. The first sheet feeding module 70 is a part of the image formation device 10, and stores or supplies sheets having a predetermined size. The first sheet feeding module 70 includes a first sheet feeding module housing 71. The first sheet feeding module housing 71 is one example of a “fifth housing”. As one example, as shown in FIG. 1, the first sheet feeding module housing 71 is connected to a lower side surface of the housing 12 in the left direction. Namely, the first sheet feeding module housing 71 is connected to the housing 12 from a side opposite to a side to which the post-processing module 14 is connected.

The first sheet feeding module housing 71 includes a first sheet feeding module inclined portion 72 at an upper end portion 75 of a front surface of the housing. The first sheet feeding module inclined portion 72 is one example of a “fifth inclined portion”. The first sheet feeding module inclined portion 72 is formed to be continuous with the lower inclined portion 32 of the housing 12. Namely, the first sheet feeding module inclined portion 72 is provided on an extension line of the lower inclined portion 32.

The first sheet feeding module housing 71 includes a first sheet feeding module cover 71A. The first sheet feeding module cover 71A is openable and closable, and an internal structure of the first sheet feeding module housing 71 is exposed to the outside by opening the first sheet feeding module cover 71A. As one example, the first sheet feeding module cover 71A is a single-swing door that is openable and closable by a vertical hinge. The first sheet feeding module cover 71A is one example of a “fifth cover portion”.

The first sheet feeding module cover 71A is provided on the front surface of the first sheet feeding module housing 71. The first sheet feeding module cover 71A is provided with the first sheet feeding module inclined portion 72. In addition, a through-hole is provided in the first sheet feeding module inclined portion 72 of the first sheet feeding module cover 71A at a position corresponding to a first sheet feeding module notification unit 74 to be described later. Accordingly, the first sheet feeding module notification unit 74 becomes visible to an operator.

### (First Sheet Feeding Module Housing Handle)

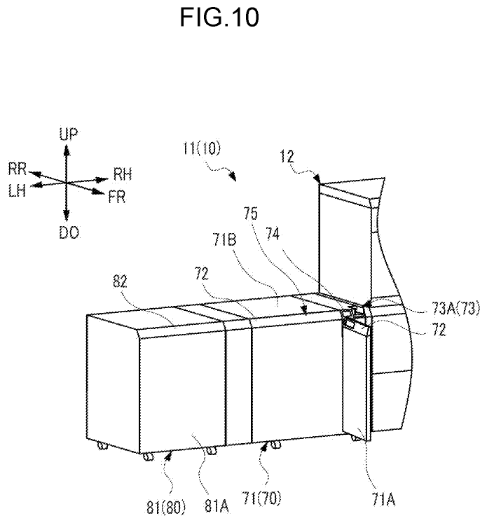

FIG. 10 is a perspective view showing the first sheet feeding module housing 71 in an enlarged manner. As shown in FIG. 10, the first sheet feeding module housing 71 includes a first sheet feeding module housing handle 73 for opening and closing the first sheet feeding module cover 71A. The first sheet feeding module housing handle 73 is formed to include a first sheet feeding module housing recess 73A provided on an upper surface 71B. The first sheet feeding module housing recess 73A is open upward and is open toward the first sheet feeding module inclined portion 72. The first sheet feeding module housing handle 73 is one example of a “fifth handle portion”, and the first sheet feeding module housing recess 73A is one example of a “fifth recess”.

When an operator operates the first sheet feeding module housing handle 73 to open the first sheet feeding module cover 71A, the operator inserts the fingers from above the first sheet feeding module housing recess 73A, and hooks the fingers on a grip portion of the first sheet feeding module cover 71A. In this state, the operator opens the first sheet feeding module cover 71A as shown in FIG. 10 by pulling the first sheet feeding module housing handle 73 toward the front side of the first sheet feeding module housing 71. As a result, an internal structure of the first sheet feeding module housing 71 is exposed.

### (First Sheet Feeding Module Notification Unit)

As shown in FIG. 10, the first sheet feeding module housing 71 includes the first sheet feeding module notification unit 74 on the first sheet feeding module inclined portion 72. The first sheet feeding module notification unit 74 is one example of a “third notification unit”. The first sheet feeding module notification unit 74 makes a notification regarding an operation state of the first sheet feeding module 70.

As one example, the first sheet feeding module notification unit 74 notifies that a sheet jam has occurred in a conveyance path inside the first sheet feeding module 70. Examples of the first sheet feeding module notification unit 74 include a lighting device such as a light emitting diode (LED) lamp and a screen display device such as a liquid crystal display or an electronic luminescent (EL) display.

The first sheet feeding module notification unit 74 is disposed to fit within an inclined surface of the first sheet feeding module inclined portion 72. Namely, an upper end edge of the first sheet feeding module notification unit 74 is lower than an upper end of the first sheet feeding module inclined portion 72. In addition, a lower end edge of the first sheet feeding module notification unit 74 is higher than a lower end of the first sheet feeding module inclined portion 72.

### (Second Sheet Feeding Module Housing)

As shown in FIG. 1, the image formation device 10 may further include a second sheet feeding module 80. The second sheet feeding module 80 is a part of the image formation device 10, and stores or supplies sheets having a predetermined size. The second sheet feeding module 80 includes a second sheet feeding module housing 81. The second sheet feeding module housing 81 is one example of a “sixth housing”. As one example, as shown in FIG. 1, the second sheet feeding module housing 81 is connected to a side surface of the first sheet feeding module housing 71 in the left direction.

The second sheet feeding module housing 81 includes a second sheet feeding module inclined portion 82 at an upper end portion 85 of a front surface of the housing. The second sheet feeding module inclined portion 82 is one example of a “sixth inclined portion”. The second sheet feeding module inclined portion 82 is formed to be continuous with the first sheet feeding module inclined portion 72. Namely, the second sheet feeding module inclined portion 82 is provided on an extension line of the first sheet feeding module inclined portion 72.

The second sheet feeding module housing 81 includes a second sheet feeding module cover 81A. The second sheet feeding module cover 81A is openable and closable, and an internal structure of the second sheet feeding module housing 81 is exposed to the outside by opening the second sheet feeding module cover 81A. As one example, the second sheet feeding module cover 81A is a single-swing door that is openable and closable by a vertical hinge. The second sheet feeding module cover 81A is one example of a “sixth cover portion”.

The second sheet feeding module cover 81A is provided on the front surface of the second sheet feeding module housing 81. The second sheet feeding module cover 81A is provided with the second sheet feeding module inclined portion 82. In addition, a through-hole is provided in the second sheet feeding module inclined portion 82 of the second sheet feeding module cover 81A at a position corresponding to a second sheet feeding module notification unit 84 to be described later. Accordingly, the second sheet feeding module notification unit 84 becomes visible to an operator.

### (Second Sheet Feeding Module Housing Handle)

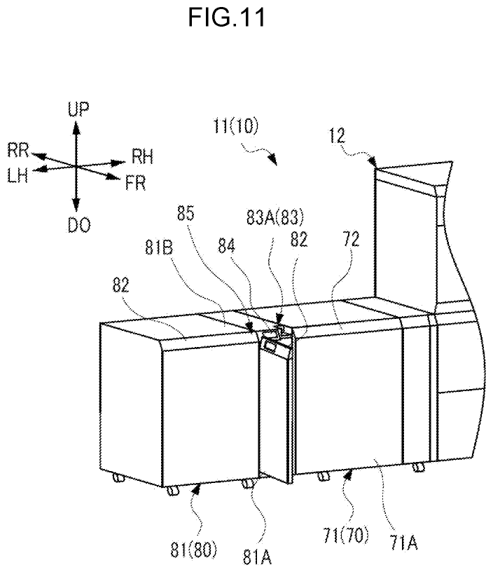

FIG. 11 is a perspective view showing the second sheet feeding module housing 81 in an enlarged manner. As shown in FIG. 11, the second sheet feeding module housing 81 includes a second sheet feeding module housing handle 83 for opening and closing the second sheet feeding module cover 81A. The second sheet feeding module housing handle 83 is formed to include a second sheet feeding module housing recess 83A provided on an upper surface 81B. The second sheet feeding module housing recess 83A is open upward and is open toward the second sheet feeding module inclined portion 82. The second sheet feeding module housing handle 83 is one example of a “sixth handle portion”, and the second sheet feeding module housing recess 83A is one example of a “sixth recess”.

When an operator operates the second sheet feeding module housing handle 83 to open the second sheet feeding module cover 81A, the operator inserts the fingers from above the second sheet feeding module housing recess 83A, and hooks the fingers on a grip portion of the second sheet feeding module cover 81A. In this state, the operator opens the second sheet feeding module cover 81A as shown in FIG. 11 by pulling the second sheet feeding module housing handle 83 toward the front side of the second sheet feeding module housing 81. As a result, an internal structure of the second sheet feeding module housing 81 is exposed.

### (Second Sheet Feeding Module Notification Unit)

As shown in FIG. 11, the second sheet feeding module housing 81 includes the second sheet feeding module notification unit 84 on the second sheet feeding module inclined portion 82. The second sheet feeding module notification unit 84 is one example of a “fourth notification unit”. The second sheet feeding module notification unit 84 makes a notification regarding an operation state of the second sheet feeding module 80. As one example, the second sheet feeding module notification unit 84 notifies that a sheet jam has occurred in a conveyance path inside the second sheet feeding module 80. Examples of the second sheet feeding module notification unit 84 include a lighting device such as a light emitting diode (LED) lamp and a screen display device such as a liquid crystal display or an electronic luminescent (EL) display.

The second sheet feeding module notification unit 84 is disposed to fit within an inclined surface of the second sheet feeding module inclined portion 82. Namely, an upper end edge of the second sheet feeding module notification unit 84 is lower than an upper end of the second sheet feeding module inclined portion 82. In addition, a lower end edge of the second sheet feeding module notification unit 84 is higher than a lower end of the second sheet feeding module inclined portion 82.

### Actions Related to Present Embodiment

In the upper inclined portion 22 of the housing structure 11, the distal end portion 24 is located on the inclined surface of the upper inclined portion 22, and the housing handle 23 formed to include the grip portion 25 on the side opposite to the inclined surface of the upper inclined portion 22 is provided. For this reason, compared to a case in which a separate handle protruding to the outside of the housing is attached to the inclined portion of the housing, the continuity of the upper inclined portion 22 is maintained, and the aesthetic appeal is improved. In addition, since the housing handle 23 is provided on the upper inclined portion 22, the line of sight of an operator is guided, so that the operator can easily recognize the position of the housing handle 23.

In addition, in the present embodiment, the covering portion 33 that is provided below the distal end portion 24 of the housing handle 23 and that covers the upper end surface 31A of the lower cover portion 30 is provided. For this reason, compared to a configuration without the covering portion 33, it becomes difficult to view the upper end surface 31A of the lower cover portion 30, and the aesthetic appeal is improved. Namely, in a case where the colors of the upper cover portion 20 and the lower cover portion 30 are different, the upper end surface 31A of the lower cover portion 30 may be easily recognized due to the difference in color. Therefore, the upper end surface 31A of the lower cover portion 30 is covered with the covering portion 33, so that the aesthetic appeal is improved.

In addition, in the present embodiment, the covering portion 33 is inclined in the same direction as the lower inclined portion 32. For this reason, compared to a case in which the covering portion 33 is not inclined in the same direction as the lower inclined portion 32, it becomes difficult for an operator to view the upper end surface 31A of the lower cover portion 30 even though the space is saved, and the aesthetic appeal is improved.

Namely, in a case in which the upper end surface 31A of the lower cover portion 30 is recognized when the operator views the housing handle 23 from above, the aesthetic appeal deteriorates. In order to make it difficult to recognize the upper end surface 31A of the lower cover portion 30, for example, a configuration in which the length of the housing handle 23 in the front-rear direction (namely, depth) is increased and the upper end surface 31A is disposed on the rear can be considered. In this case, the size of the housing handle 23 is increased, and the opening 27 is also increased. Therefore, the covering portion 33 is provided to make it difficult to recognize the upper end surface 31A of the lower cover portion 30. In this case, since the covering portion 33 is inclined in the same direction as the lower inclined portion 32, the upper end surface 31A is covered without increasing the depth (namely, the length in the front-rear direction) of the housing handle 23, and the aesthetic appeal is improved.

In addition, in the present embodiment, since the upper inclined portion 22 is formed over the lower end portion 21 of the upper cover portion 20, compared to a case in which the upper inclined portion 22 is provided only at a part of the lower end portion 21 of the upper cover portion 20, the continuity of the upper inclined portion 22 is maintained, and the aesthetic appeal is improved.

In addition, in the present embodiment, since the lower inclined portion 32 is formed over the upper end portion 31 of the lower cover portion 30, compared to a case in which the lower inclined portion 32 is provided only at a part of the upper end portion 31 of the lower cover portion 30, the continuity of the lower inclined portion 32 is maintained, and the aesthetic appeal is improved.

In addition, in the present embodiment, the housing structure 11 includes the post-processing module housing 15 connected to the housing 12, and the post-processing module housing 15 includes the post-processing module inclined portion 16 formed to be continuous with the lower inclined portion 32. For this reason, compared to a case in which the lower inclined portion 32 is not continuous to the post-processing module housing 15, the continuity between the post-processing module inclined portion 16 and the lower inclined portion 32 is maintained, and the aesthetic appeal is improved.

In addition, in the present embodiment, the post-processing module housing 15 includes the post-processing module housing handle 40. The post-processing module housing handle 40 includes the post-processing module housing recess 41 that is provided on the upper surface 15C of the post-processing module housing 15 and that is open toward the post-processing module inclined portion 16. For this reason, compared to a case in which a separate handle protruding to the outside of the housing is attached to the inclined portion of the housing, the continuity of the post-processing module inclined portion 16 is maintained, and the aesthetic appeal is improved.

Namely, since the post-processing module housing recess 41 is provided on the upper surface 15C, compared to a case in which a handle is formed by providing a recess in the post-processing module inclined portion 16, the shape of the post-processing module inclined portion 16 does not change between a portion with the handle and a portion without the handle, so that the continuity of the post-processing module inclined portion 16 is maintained and the aesthetic appeal is improved.

In addition, in the present embodiment, the post-processing module housing handle 40 includes the post-processing module housing recess 41 provided on the upper surface 15C of the post-processing module housing 15. For this reason, the post-processing module housing handle 40 is provided in the vicinity of the post-processing module inclined portion 16, so that the heights of the post-processing module housing handle 40 and the housing handle 23 become close to each other. Therefore, an operator easily recognizes the position of the post-processing module housing handle 40.

In addition, in the present embodiment, the housing structure 11 includes the post-processing module housing 15 connected to the housing 12. The post-processing module housing 15 includes the post-processing module inclined portion 16 formed to be continuous with the lower inclined portion 32. For this reason, compared to a case in which the lower inclined portion 32 is not continuous to the post-processing module housing 15, the continuity between the lower inclined portion 32 and the post-processing module inclined portion 16 is maintained, and the aesthetic appeal is improved.

In addition, in the present embodiment, the post-processing module housing 15 includes the post-processing module housing handle 40. The post-processing module housing handle 40 includes the post-processing module housing recess 41 that is provided on the upper surface 15C of the post-processing module housing 15 and that is open toward the post-processing module inclined portion 16. For this reason, compared to a case in which a separate handle protruding to the outside of the housing is attached to the inclined portion of the housing, the continuity of the post-processing module inclined portion 16 is maintained, and the aesthetic appeal is improved. In addition, in the present embodiment, compared to a case in which a handle is formed by providing a recess in the inclined portion, the shape of the post-processing module inclined portion 16 does not change between a portion with the handle and a portion without the handle, so that the continuity of the post-processing module inclined portion 16 is maintained and the aesthetic appeal is improved.

In addition, in the present embodiment, the housing structure 11 includes the first sheet ejection module housing 51 connected to the post-processing module housing 15. The first sheet ejection module housing 51 includes the first sheet ejection module inclined portion 52 formed to be continuous with the post-processing module inclined portion 16. For this reason, compared to a case in which the post-processing module inclined portion 16 is not continuous to the first sheet ejection module housing 51, the continuity between the post-processing module inclined portion 16 and the first sheet ejection module inclined portion 52 is maintained, and the aesthetic appeal is improved.

In addition, in the present embodiment, the first sheet ejection module housing 51 includes the first sheet ejection module housing handle 53. The first sheet ejection module housing handle 53 includes the first sheet ejection module housing recess 53A that is provided on the upper surface 51B of the first sheet ejection module housing 51 and that is open toward the first sheet ejection module inclined portion 52. For this reason, compared to a case in which a separate handle protruding to the outside of the housing is attached to the inclined portion of the housing, the continuity of the first sheet ejection module inclined portion 52 is maintained, and the aesthetic appeal is improved. In addition, in the present embodiment, compared to a case in which a handle is formed by providing a recess in the inclined portion, the shape of the first sheet ejection module inclined portion 52 does not change between a portion with the handle and a portion without the handle, so that the continuity of the first sheet ejection module inclined portion 52 is maintained and the aesthetic appeal is improved.

In addition, in the present embodiment, the first sheet ejection module housing handle 53 includes the first sheet ejection module housing recess 53A provided on the upper surface 51B of the first sheet ejection module housing 51. For this reason, the first sheet ejection module housing handle 53 is provided in the vicinity of the first sheet ejection module inclined portion 52, so that the heights of the first sheet ejection module housing handle 53 and the post-processing module housing handle 40 become close to each other. Therefore, an operator easily recognizes the position of the first sheet ejection module housing handle 53.

In addition, in the present embodiment, the first sheet ejection module 50 includes the first sheet ejection module notification unit 54 on the first sheet ejection module inclined portion 52. For this reason, compared to a case in which the first sheet ejection module notification unit 54 is provided at a portion other than the first sheet ejection module inclined portion 52, the position of the first sheet ejection module notification unit 54 is easily understood. Namely, since the line of sight of an operator is guided along the first sheet ejection module inclined portion 52, the position of the first sheet ejection module notification unit 54 is easily recognized by the operator. At this time, in a case in which the first sheet ejection module notification unit 54 has a planar shape of an LED lamp or the like as one example, since the first sheet ejection module notification unit 54 can be formed along the inclined surface, compared to the case of a notification unit having a shape protruding from the inclined surface, the position of the first sheet ejection module notification unit 54 can be easily recognized while suppressing a degradation in aesthetic appeal as one element of the first sheet ejection module inclined portion 52.

In addition, in the present embodiment, the housing structure 11 includes the second sheet ejection module housing 61 connected to the first sheet ejection module housing 51. The second sheet ejection module housing 61 includes the second sheet ejection module inclined portion 62 formed to be continuous with the first sheet ejection module inclined portion 52. For this reason, compared to a case in which the first sheet ejection module inclined portion 52 is not continuous to the second sheet ejection module housing 61, the continuity between the first sheet ejection module inclined portion 52 and the second sheet ejection module inclined portion 62 is maintained, and the aesthetic appeal is improved.

In addition, in the present embodiment, the second sheet ejection module housing 61 includes the second sheet ejection module housing handle 63. The second sheet ejection module housing handle 63 includes the second sheet ejection module housing recess 63A that is provided on the upper surface of the second sheet ejection module housing 61 and that is open toward the second sheet ejection module inclined portion 62. For this reason, compared to a case in which a separate handle protruding to the outside of the housing is attached to the inclined portion of the housing, the continuity of the second sheet ejection module inclined portion 62 is maintained, and the aesthetic appeal is improved. In addition, in the present embodiment, compared to a case in which a handle is formed by providing a recess in the inclined portion, the shape of the second sheet ejection module inclined portion 62 does not change between a portion with the handle and a portion without the handle, so that the continuity of the second sheet ejection module inclined portion 62 is maintained and the aesthetic appeal is improved.

In addition, in the present embodiment, the second sheet ejection module housing handle 63 includes the second sheet ejection module housing recess 63A provided on the upper surface 61B of the second sheet ejection module housing 61. For this reason, the second sheet ejection module housing handle 63 is provided in the vicinity of the second sheet ejection module inclined portion 62, so that the heights of the second sheet ejection module housing handle 63 and the housing handle 23, the post-processing module housing handle 40, or the first sheet ejection module housing handle 53 become close to each other. Therefore, an operator easily recognizes the position of the second sheet ejection module housing handle 63.

In addition, in the present embodiment, the second sheet ejection module 60 includes the second sheet ejection module notification unit 64 on the second sheet ejection module inclined portion 62. For this reason, compared to a case in which the second sheet ejection module notification unit 64 is provided at a portion other than the second sheet ejection module inclined portion 62, the position of the notification unit is easily understood. Namely, since the line of sight of an operator is guided along the second sheet ejection module inclined portion 62, the position of the second sheet ejection module notification unit 64 is easily recognized by the operator. At this time, in a case in which the second sheet ejection module notification unit 64 has a planar shape of an LED lamp or the like as one example, since the second sheet ejection module notification unit 64 can be formed along the inclined surface, compared to the case of a notification unit having a shape protruding from the inclined surface, the position of the second sheet ejection module notification unit 64 can be easily recognized while suppressing a degradation in aesthetic appeal as one element of the second sheet ejection module inclined portion 62.

In addition, in the present embodiment, the housing structure 11 includes the first sheet feeding module housing 71 connected to the housing 12 from the side opposite to the side to which the post-processing module housing 15 is connected. The first sheet feeding module housing 71 includes the first sheet feeding module inclined portion 72 formed to be continuous with the lower inclined portion 32. For this reason, compared to a case in which the lower inclined portion 32 is not continuous to the first sheet feeding module housing 71, the continuity between the lower inclined portion 32 and the first sheet feeding module inclined portion 72 is maintained, and the aesthetic appeal is improved.

In addition, in the present embodiment, the first sheet feeding module housing 71 includes the first sheet feeding module housing handle 73. The first sheet feeding module housing handle 73 includes the first sheet feeding module housing recess 73A that is provided on the upper surface 71B of the first sheet feeding module housing 71 and that is open toward the first sheet feeding module inclined portion 72. For this reason, compared to a case in which a separate handle protruding to the outside of the housing is attached to the inclined portion of the housing, the continuity of the first sheet feeding module inclined portion 72 is maintained, and the aesthetic appeal is improved. In addition, in the present embodiment, compared to a case in which a handle is formed by providing a recess in the inclined portion, the shape of the first sheet feeding module inclined portion 72 does not change between a portion with the handle and a portion without the handle, so that the continuity of the first sheet feeding module inclined portion 72 is maintained and the aesthetic appeal is improved.

In addition, in the present embodiment, the first sheet feeding module housing handle 73 includes the first sheet feeding module housing recess 73A provided on the upper surface 71B of the first sheet feeding module housing 71. For this reason, the first sheet feeding module housing handle 73 is provided in the vicinity of the first sheet feeding module inclined portion 72, so that the heights of the first sheet feeding module housing handle 73 and the housing handle 23 become close to each other. Therefore, an operator easily recognizes the position of the handle.

In addition, in the present embodiment, the first sheet feeding module 70 includes the first sheet feeding module notification unit 74 on the first sheet feeding module inclined portion 72. For this reason, compared to a case in which the first sheet feeding module notification unit 74 is provided at a portion other than the first sheet feeding module inclined portion 72, the position of the notification unit is easily understood. Namely, since the line of sight of an operator is guided along the first sheet feeding module inclined portion 72, the position of the first sheet feeding module notification unit 74 is easily recognized by the operator. At this time, in a case in which the first sheet feeding module notification unit 74 has a planar shape of an LED lamp or the like as one example, since the first sheet feeding module notification unit 74 can be formed along the inclined surface, compared to the case of a notification unit having a shape protruding from the inclined surface, the position of the first sheet feeding module notification unit 74 can be easily recognized while suppressing a degradation in aesthetic appeal as one element of the first sheet feeding module inclined portion 72.

In addition, in the present embodiment, the housing structure 11 includes the second sheet feeding module housing 81 connected to the first sheet feeding module housing 71. The second sheet feeding module housing 81 includes the second sheet feeding module inclined portion 82 formed to be continuous with the first sheet feeding module inclined portion 72. For this reason, compared to a case in which the first sheet feeding module inclined portion 72 is not continuous to the second sheet feeding module housing 81, the continuity of the second sheet feeding module inclined portion 82 is maintained, and the aesthetic appeal is improved.

In addition, in the present embodiment, the second sheet feeding module housing 81 includes the second sheet feeding module housing handle 83. The second sheet feeding module housing handle 83 includes the second sheet feeding module housing recess 83A that is provided on the upper surface of the second sheet feeding module housing 81 and that is open toward the second sheet feeding module inclined portion 82. For this reason, compared to a case in which a separate handle protruding to the outside of the housing is attached to the inclined portion of the housing, the continuity of the second sheet feeding module inclined portion 82 is maintained, and the aesthetic appeal is improved. In addition, in the present embodiment, compared to a case in which a handle is formed by providing a recess in the inclined portion, the shape of the second sheet feeding module inclined portion 82 does not change between a portion with the handle and a portion without the handle, so that the continuity of the second sheet feeding module inclined portion 82 is maintained and the aesthetic appeal is improved.

In addition, in the present embodiment, the second sheet feeding module housing handle 83 includes the second sheet feeding module housing recess 83A provided on the upper surface 81B of the second sheet feeding module housing 81. For this reason, the second sheet feeding module housing handle 83 is provided in the vicinity of the second sheet feeding module inclined portion 82, so that the heights of the second sheet feeding module housing handle 83 and the housing handle 23 or the first sheet feeding module housing handle 73 become close to each other. Therefore, an operator easily recognizes the position of the second sheet feeding module housing handle 83.

In addition, in the present embodiment, the second sheet feeding module 80 includes the second sheet feeding module notification unit 84 on the second sheet feeding module inclined portion 82. For this reason, compared to a case in which the second sheet feeding module notification unit 84 is provided at a portion other than the second sheet feeding module inclined portion 82, the position of the second sheet feeding module notification unit 84 is easily understood. Namely, since the line of sight of an operator is guided along the second sheet feeding module inclined portion 82, the position of the second sheet feeding module notification unit 84 is easily recognized by the operator. At this time, in a case in which the second sheet feeding module notification unit 84 has a planar shape of an LED lamp or the like as one example, since the second sheet feeding module notification unit 84 can be formed along the inclined surface, compared to the case of a notification unit having a shape protruding from the inclined surface, the position of the second sheet feeding module notification unit 84 is easily recognized while suppressing a degradation in aesthetic appeal as one element of the second sheet feeding module inclined portion 82.

In the present embodiment, since the image formation device 10 includes the housing structure 11, compared to a case in which the housing structure 11 is not provided, the continuity of the inclined portion is maintained, and the aesthetic appeal is improved.

### Modification Examples

In the present embodiment, the form example in which in the housing structure 11, the cover portion 13 includes the upper cover portions 20 and the lower cover portions 30, and the entirety of the cover portion 13 is opened by pulling the housing handles 23 has been described as an example; however, the art of the disclosure is not limited thereto. For example, a configuration in which the cover portion 13 is not divided into an upper portion and a lower portion but is integrally formed may be implemented.

In the present embodiment, the form example in which the cover is opened by pulling the cover toward the front side of the housing has been described as an example; however, the art of the disclosure is not limited thereto. For example, the cover may be configured to be opened by sliding the cover in the left-right direction.

In the present embodiment, the form example in which the housing structure 11 includes the post-processing module housing 15, the first sheet ejection module 50, the second sheet ejection module 60, the first sheet feeding module 70, and the second sheet feeding module 80 has been described as an example; however, the art of the disclosure is not limited thereto. For example, a configuration in which the housing structure 11 includes only the housing 12 may be implemented, or a configuration in which only the post-processing module housing 15 is connected to the housing 12 may be implemented.

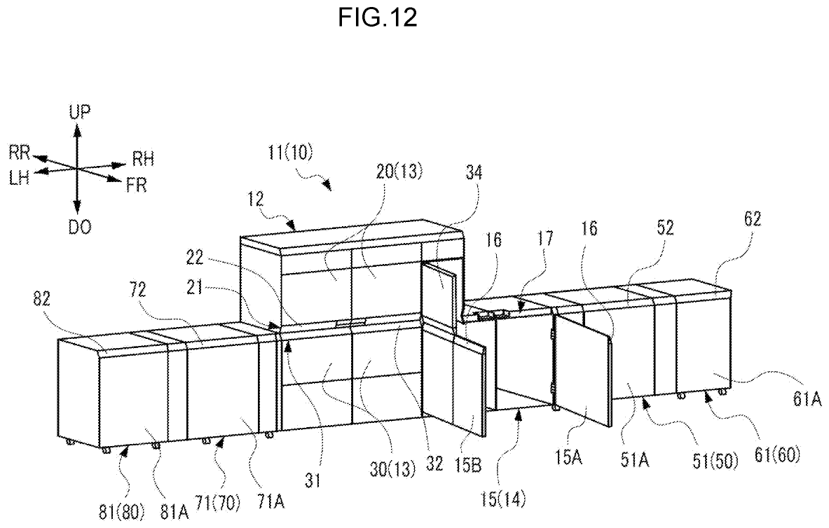

In the present embodiment, the form example in which the post-processing module housing 15 is connected to the housing 12 has been described as an example; however, the art of the disclosure is not limited thereto. For example, a configuration in which the housing 12 and the post-processing module housing 15 are integrally formed may be implemented. In this configuration, as shown in FIG. 12, the cover of the housing 12 may be configured to be integrally opened by operating the post-processing module housing handle 40. Specifically, the post-processing module left cover portion 15B and a housing right cover portion 34 are integrated. The inside of the post-processing module housing 15 and the right inside of the housing 12 are exposed by pulling the post-processing module housing handle 40 forward.

In the present embodiment, the form example in which the housing 12 and the post-processing module housing 15 are disposed in such a manner that the positions of the front surfaces are the same has been described as an example; however, the art of the disclosure is not limited thereto. For example, the front surface of the post-processing module housing 15 may be disposed several centimeters behind the front surface of the housing 12 in the front-rear direction.

In the present embodiment, the form example in which the image formation device 10 includes the housing structure 11 has been described as an example; however, the art of the disclosure is not limited thereto. For example, the housing structure 11 is applicable as a housing structure for machine tools, power supply devices, large computers, kitchen equipment, storage devices, and the like.

The disclosure is not limited to the embodiment described above, and various modifications, changes, and improvements can be made without departing the concept of the disclosure. For example, a plurality of the modification examples described above may be combined as appropriate.

The content of Japanese Patent Application No. 2021-126952 filed on Aug. 2, 2021 is incorporated in the present specification by reference in its entirety.

All documents, patent applications, and technical standards described in the present specification are incorporated in the present specification by reference to the same extent as if each individual document, patent application, and technical standard are specifically and individually indicated to be incorporated by reference.

Regarding the above-described embodiment, the following supplementary notes are further disclosed.

### (Supplementary Note 1)

A housing structure including:
a cover portion including a first cover portion provided on one surface of a first housing, and a second cover portion provided on the one surface of the first housing below the first cover portion;
a first inclined portion provided at a lower end portion of the first cover portion and inclined toward an inside of the first housing;
a second inclined portion provided at an upper end portion of the second cover portion and inclined toward the inside of the first housing; and
a first handle portion which is a handle for opening and closing the cover portion, in which a distal end portion of the handle is located on an inclined surface of the first inclined portion, and which is formed to include a grip portion of the handle on a side opposite to the inclined surface of the first inclined portion.

### (Supplementary Note 2)

The housing structure according to Supplementary Note 1,
in which a covering portion provided below the distal end portion of the first handle portion and covering an upper end surface of the second cover portion is provided.

### (Supplementary Note 3)

The housing structure according to Supplementary Note 2,
in which the covering portion is inclined in the same direction as the second inclined portion.

### (Supplementary Note 4)

The housing structure according to any one of Supplementary Notes 1 to 3,
in which the first inclined portion is formed over the lower end portion of the first cover portion.

### (Supplementary Note 5)

The housing structure according to any one of Supplementary Notes 1 to 4,
in which the second inclined portion is formed over the upper end portion of the second cover portion.

### (Supplementary Note 6)

The housing structure according to any one of Supplementary Notes 1 to 5,
in which the housing structure includes a second housing connected to the first housing, and
the second housing includes a second housing inclined portion provided at an upper end portion of a surface on the same side as the one surface and formed to be continuous with the second inclined portion.

### (Supplementary Note 7)

The housing structure according to Supplementary Note 6,
in which the second housing includes a second housing cover portion provided on the surface on the same side as the one surface of the first housing and provided with the second housing inclined portion, and a second handle portion for opening and closing the second housing cover portion, and
the second handle portion is formed to include a second housing recess provided on an upper surface of the second housing and open toward the second housing inclined portion.

### (Supplementary Note 8)

The housing structure according to Supplementary Note 6 or 7,
in which the housing structure includes a third housing connected to the second housing, and
the third housing includes a third inclined portion provided at an upper end portion of a surface on the same side as the one surface and formed to be continuous with the second housing inclined portion.

### (Supplementary Note 9)

The housing structure according to Supplementary Note 8,
in which the third housing includes a third cover portion provided on the surface on the same side as the one surface of the first housing and provided with the third inclined portion, and a third handle portion for opening and closing the third cover portion, and
the third handle portion is formed to include a third recess provided on an upper surface of the third housing and open toward the third inclined portion.

### (Supplementary Note 10)

The housing structure according to Supplementary Note 8 or 9,
in which the third inclined portion is provided with a first notification unit.

### (Supplementary Note 11)

The housing structure according to any one of Supplementary Notes 8 to 10,
in which the housing structure includes a fourth housing connected to the third housing, and
the fourth housing includes a fourth inclined portion provided at an upper end portion of a surface on the same side as the one surface and formed to be continuous with the third inclined portion.

### (Supplementary Note 12)

The housing structure according to Supplementary Note 11,
in which the fourth housing includes a fourth cover portion provided on the surface on the same side as the one surface of the first housing and provided with the fourth inclined portion, and a fourth handle portion for opening and closing the fourth cover portion, and
the fourth handle portion is formed to include a fourth recess provided on an upper surface of the fourth housing and open toward the fourth inclined portion.

### (Supplementary Note 13)

The housing structure according to Supplementary Note 11 or 12,
in which the fourth inclined portion is provided with a second notification unit.

### (Supplementary Note 14)

The housing structure according to any one of Supplementary Notes 6 to 13,
in which the housing structure includes a fifth housing connected to a side opposite to a side on which the second housing is connected to the first housing, and
the fifth housing includes a fifth inclined portion provided at an upper end portion of a surface on the same side as the one surface and formed to be continuous with the second inclined portion.

### (Supplementary Note 15)

The housing structure according to Supplementary Note 14,
in which the fifth housing includes a fifth cover portion provided on the surface on the same side as the one surface of the first housing and provided with the fifth inclined portion, and a fifth handle portion for opening and closing the fifth cover portion, and
the fifth handle portion is formed to include a fifth recess provided on an upper surface of the fifth housing and open toward the fifth inclined portion.

### (Supplementary Note 16)

The housing structure according to Supplementary Note 14 or 15,
in which the fifth inclined portion is provided with a third notification unit.

### (Supplementary Note 17)

The housing structure according to any one of Supplementary Notes 14 to 16,
in which the housing structure includes a sixth housing connected to the fifth housing, and
the sixth housing includes a sixth inclined portion provided at an upper end portion of a surface on the same side as the one surface and formed to be continuous with the fifth inclined portion.

### (Supplementary Note 18)

The housing structure according to Supplementary Note 17,
in which the sixth housing includes a sixth cover portion provided on the surface on the same side as the one surface of the first housing and provided with the sixth inclined portion, and a sixth handle portion for opening and closing the sixth cover portion, and
the sixth handle portion is formed to include a sixth recess provided on an upper surface of the sixth housing and open toward the sixth inclined portion.

### (Supplementary Note 19)

The housing structure according to Supplementary Note 17 or 18,
in which the sixth inclined portion is provided with a fourth notification unit.

### (Supplementary Note 20)

An image formation device including:
the housing structure according to any one of Supplementary Notes 1 to 19.

1. A housing structure, comprising:
a cover portion including a first cover portion provided on one surface of a first housing, and a second cover portion provided on the one surface of the first housing below the first cover portion;
a first inclined portion provided at a lower end portion of the first cover portion and inclined toward an inner side of the first housing;
a second inclined portion provided at an upper end portion of the second cover portion and inclined toward the inner side of the first housing; and
a first handle portion, which is a handle for opening and closing the cover portion, in which a distal end portion of the handle is located on an inclined surface of the first inclined portion, and which is formed to include a grip portion of the handle on an opposite side from the inclined surface of the first inclined portion.

2. The housing structure according to claim 1, further comprising a covering portion provided below the distal end portion of the first handle portion and covering an upper end surface of the second cover portion.

3. The housing structure according to claim 2, wherein the covering portion is inclined in the same direction as the second inclined portion.

4. The housing structure according to claim 1, wherein the first inclined portion is formed over the lower end portion of the first cover portion.

5. The housing structure according to claim 1, wherein the second inclined portion is formed over the upper end portion of the second cover portion.

6. The housing structure according to claim 1, wherein:
the housing structure includes a second housing connected to the first housing, and
the second housing includes a second housing inclined portion provided at an upper end portion of a surface on the same side as the one surface and formed to be continuous with the second inclined portion.

7. The housing structure according to claim 6, wherein:
the second housing includes a second housing cover portion provided on the surface on the same side as the one surface of the first housing and provided with the second housing inclined portion, and a second handle portion for opening and closing the second housing cover portion, and
the second handle portion is formed to include a second housing recess provided on an upper surface of the second housing and open toward the second housing inclined portion.

8. The housing structure according to claim 6, wherein:
the housing structure includes a third housing connected to the second housing, and
the third housing includes a third inclined portion provided at an upper end portion of a surface on the same side as the one surface and formed to be continuous with the second housing inclined portion.

9. The housing structure according to claim 8, wherein:
the third housing includes a third cover portion provided on the surface on the same side as the one surface of the first housing and provided with the third inclined portion, and a third handle portion for opening and closing the third cover portion, and
the third handle portion is formed to include a third recess provided on an upper surface of the third housing and open toward the third inclined portion.

10. The housing structure according to claim 8, wherein the third inclined portion is provided with a first notification unit.

11. The housing structure according to claim 8, wherein:
the housing structure includes a fourth housing connected to the third housing, and
the fourth housing includes a fourth inclined portion provided at an upper end portion of a surface on the same side as the one surface and formed to be continuous with the third inclined portion.

12. The housing structure according to claim 11, wherein:
the fourth housing includes a fourth cover portion provided on the surface on the same side as the one surface of the first housing and provided with the fourth inclined portion, and a fourth handle portion for opening and closing the fourth cover portion, and
the fourth handle portion is formed to include a fourth recess provided on an upper surface of the fourth housing and open toward the fourth inclined portion.

13. The housing structure according to claim 11, wherein the fourth inclined portion is provided with a second notification unit.

14. The housing structure according to claim 6, wherein:
the housing structure includes a fifth housing connected to an opposite side from a side on which the second housing is connected to the first housing, and
the fifth housing includes a fifth inclined portion provided at an upper end portion of a surface on the same side as the one surface and formed to be continuous with the second inclined portion.

15. The housing structure according to claim 14, wherein:
the fifth housing includes a fifth cover portion provided on the surface on the same side as the one surface of the first housing and provided with the fifth inclined portion, and a fifth handle portion for opening and closing the fifth cover portion, and
the fifth handle portion is formed to include a fifth recess provided on an upper surface of the fifth housing and open toward the fifth inclined portion.

16. The housing structure according to claim 14, wherein the fifth inclined portion is provided with a third notification unit.

17. The housing structure according to claim 14, wherein:
the housing structure includes a sixth housing connected to the fifth housing, and
the sixth housing includes a sixth inclined portion provided at an upper end portion of a surface on the same side as the one surface and formed to be continuous with the fifth inclined portion.

18. The housing structure according to claim 17, wherein:
the sixth housing includes a sixth cover portion provided on the surface on the same side as the one surface of the first housing and provided with the sixth inclined portion, and a sixth handle portion for opening and closing the sixth cover portion, and
the sixth handle portion is formed to include a sixth recess provided on an upper surface of the sixth housing and open toward the sixth inclined portion.

19. The housing structure according to claim 17, wherein the sixth inclined portion is provided with a fourth notification unit.

20. An image formation device, comprising the housing structure according to claim 1.
